(19) United States
(12) Patent Application Publication
(10) Pub. No.: US 2013/0138367 A1
(43) Pub. Date: May 30, 2013

(54) REMOTE POWER OUTAGE NOTIFICATION

(71) Applicant: Verizon Patent and Licensing, Inc., Basking Ridge, NJ (US)

(72) Inventors: Luc Boivin, Holmdel, NJ (US); Jay J. Cappy, Louisville, KY (US); Brian A. Fleck, McKees Rocks, PA (US); Jean F. Dubois, Boothbay Harbor, ME (US); Alessandro M. Meynardi, Macungie, PA (US); Chung Ping Cheng, Lexington, MA (US); Martin Doehring, Northborough, MA (US)

(73) Assignee: VERIZON PATENT AND LICENSING, INC., Basking Ridge, NJ (US)

(21) Appl. No.: 13/731,749

(22) Filed: Dec. 31, 2012

Related U.S. Application Data
(63) Continuation-in-part of application No. 12/915,998, filed on Oct. 29, 2010.

(51) Int. Cl. G01R 31/08; G06F 17/00

(52) U.S. Cl. CPC G01R 31/08; G06F 17/00
USPC 702/59

(57) ABSTRACT

Power outages and restorations at telecommunications subscribers' premises can be automatically detected and reported in a manner that is sensitive to subscriber privacy concerns. A server device receives, from a network terminal device installed at a subscriber premise, an alert that the network terminal device has lost primary power from a power grid. The server device determines a physical address of a location for the network terminal and associates the physical address of the network terminal location with particular power grid equipment. The server device determines whether a power outage of the power grid has occurred and outputs a notification of the power outage associated with the particular power grid equipment when the power outage is determined to occur.

### RELATED APPLICATIONS

This application is a continuation-in-part of co-pending U.S. patent application Ser. No. 12/915,998, entitled “Remote Power Outage & Restoration Notification” for Meynardi et al. and filed on Oct. 29, 2010, the content of which is hereby incorporated by reference.

### BACKGROUND

Electrical power is transmitted via a power grid that includes a network of transmission lines, power generation stations, substations, etc., to residential, commercial and/or industrial customers. Occasionally, the power that is transmitted via the power grid may be disrupted, which may cause a power outage that affects one or more customers. Power outages may be caused by inclement weather, a manmade event (e.g., a cut transmission line due to construction), equipment malfunctions, etc.

Power providers (e.g., utilities, power utilities, cooperatives, etc.) usually respond to an outage in a reactive manner based on calls received from customers indicating that power has been lost and/or calls received from local, state or federal first responders associated with an incident potentially affecting the power grid (e.g., a vehicle hitting an electric pole, etc.). When an outage is identified, power providers initiate outage management processes or start a outage management system to manage and restore the outage. Generally, restoration of service is confirmed based on calls to and/or from customers in areas affected by the outage and/or based on physical inspections by field force personnel. Unfortunately, power providers may experience delay when detecting an outage, isolating a cause of the outage, restoring power in response to the outage, and/or confirming that power has been restored when calls are not received from customers and/or when relying on maintenance crews to perform the physical inspections.

### BRIEF DESCRIPTION OF THE DRAWINGS

FIG. 1 is a diagram of an example network in which systems and/or methods described herein may be implemented;

FIG. 2 is a diagram of exemplary components of one or more of the devices of FIG. 1;

FIG. 3 is a diagram of exemplary components of a network terminal device of FIG. 1;

FIG. 4 is a diagram of an exemplary outage notification data structure according to an implementation described herein;

FIG. 5 is a diagram of an exemplary outage event data structure according to an implementation described herein;

FIG. 6 is a diagram of an exemplary outage notification data structure according to an implementation described herein;

FIG. 7 is a diagram of an exemplary database correlation process according to an implementation described herein;

FIG. 8 is a flowchart of an exemplary process for detecting and notifying an outage/restoration according to an implementation described herein;

FIG. 9 is a flowchart of another exemplary process for detecting and notifying an outage according to an implementation described herein; and

FIG. 10 is a flowchart of an exemplary process for detecting and notifying an outage/restoration event according to an implementation described herein.

### DETAILED DESCRIPTION OF PREFERRED EMBODIMENTS

The following detailed description refers to the accompanying drawings. The same reference numbers in different drawings may identify the same or similar elements. Also, the following detailed description does not limit the invention.

Systems and methods described herein may employ devices at telecommunications subscribers' premises to automatically detect and report power outages and restorations in a manner sensitive to subscriber privacy concerns. In one implementation, a server device may receive, from a network terminal device installed at a subscriber premise, an alert that the network terminal device has lost primary power from a power grid. The server device may determine a physical address of a location for the network terminal and may associate the physical address of the network terminal location with particular power grid equipment. The server device may determine whether a power outage of the power grid has occurred and may output a notification of the power outage, associated with the particular power grid equipment, when the power outage is determined to occur. Thus, the notification of the power outage can be provided without the physical address of the network terminal location.

Alternatively, or additionally, a system may include a first server device and a second server device. The first server device may include a memory to store a subscriber data structure associating multiple network terminals devices with addresses of corresponding subscriber premises that receive power from a power grid. The first server device may be configured to receive, from a network terminal device installed at a subscriber premise, an alert that the network terminal device has lost primary power from a power grid, and determine, based on the subscriber data structure, a physical address of a location for the network terminal. The first server device may also generate a first hash value based on the physical address of the network terminal location; determine whether a power outage within the power grid has occurred; and output an indication of the power outage that includes the first hash value when the power outage is determined to have occurred. The second server device may include a memory to store an equipment data structure that relates multiple pieces of power grid equipment with second hash values derived from physical addresses of power grid customers. The second server device may be configured to receive, from the first server device, the indication of the power outage; compare the first hash value to the second hash values to identify a match; and output a notification of the power outage that identifies particular power grid equipment related to the matching one of the second hash values.

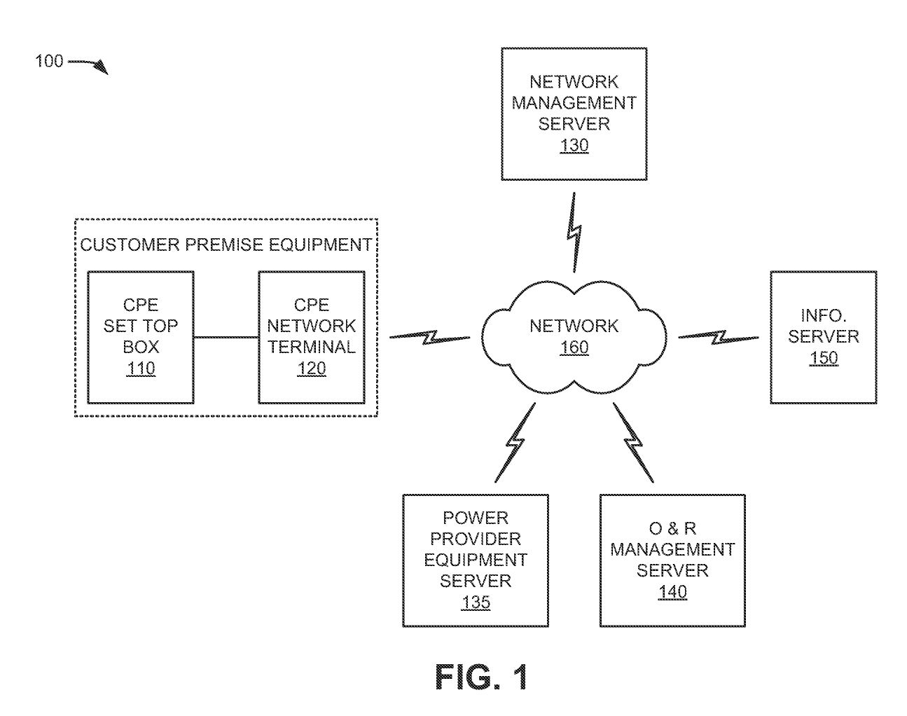

FIG. 1 is a diagram of an exemplary network 100 in which systems and/or methods described herein may be implemented. As illustrated in FIG. 1, network 100 may include a customer premises equipment (CPE) set top box (STB) 110 (hereinafter referred to as “STB 110”), a CPE network terminal 120 (hereinafter referred to as “network terminal 120”), a network management server (NMS) 130, a power provider equipment server 135 (hereinafter referred to as “PPES 135”), an outage and restoration (O&R) management server (OMS) 140 (hereinafter referred to as “O&RS 140”), and an information server 150 that are interconnected via a network 160. The number of devices and/or networks, illustrated in FIG. 1, is provided for explanatory purposes only. In practice, there may be additional devices and/or networks, fewer devices and/or networks, different devices and/or networks, or differently arranged devices and/or networks than illustrated in FIG. 1. For exemplary, there may be thousands or millions of STBs 110 and/or network terminals 120.

Also, in some implementations, one or more of the devices of network 100 may perform one or more functions described as being performed by another one or more of the devices of network 100. For example, STB 110 and network terminal 120 may be integrated into a single device. In another example, NMS 130, PPES 135 and/or O&RS 140 may be integrated into a single device. Devices of network 100 may interconnect via wired connections, wireless connections, or a combination of wired and wireless connections.

STB 110 may include a one or more devices that can receive and process an enhanced media stream and/or other traffic (e.g., Internet Protocol (IP)-based traffic), received from network 160 via network terminal 120, for display on a video display device associated with STB 110. In one exemplary implementation, STB 110 may be incorporated directly within a video display device (e.g., a television, a monitor, etc.). In another exemplary implementation, STB 110 may be replaced with a computing device (e.g., a personal computer, a laptop computer, a tablet computer, etc.), a cable card, a TV tuner card, or a portable communication device (e.g., a mobile telephone or a PDA). STB 110 may perform decoding and/or decryption functions on the enhanced media stream. STB 110 may be associated with customer premise equipment that is located within a facility (e.g., a business, a residence, etc.) associated with a user (or subscriber) of STB 110.

Network terminal 120 may include one or more computation or communication devices that are capable of communicating with network 160 and/or STB 110. For example, network terminal 120 may include a device that can receive and/or process an enhanced media stream and/or other traffic (e.g., Internet Protocol (IP)-based traffic), received from network 160, to be presented to one or more STBs 110 for display. Network terminal 120 may be associated with customer premise equipment that is located within a facility (e.g., a business, a residence, etc.) associated with a user (or subscriber) of STB 110.

Network terminal 120 may send an alert to network 160 that indicates a power state associated with network terminal 120. For example, network terminal 120 may detect that electrical power is not longer being received from an alternating current (AC) power source (e.g., via an AC power outlet connected to a power grid). Network terminal 120 may, based on the detection that AC power is no longer being received, send an outage alert which indicates that network terminal 120 is no longer receiving electrical power from the AC power source. In another example, the outage alert may identify whether network terminal 120 is operating using electrical power being received from a direct current (DC) power source (e.g., from a storage device such as a battery) and/or may identify available capacity of a DC power source associated with network terminal 120 (e.g., fully charged, partially charged, last gasp charge, etc.). In yet another example, network terminal 120 may detect that electrical power from the AC power source has been restored and may send a restore alert, which may indicate that electrical power from the AC power source has been restored. In general, network terminal 120 may thus operate from power received from the power grid. If the power from the grid fails, network terminal 120 may begin to operate from its backup battery power. The outage alert may be transmitted when network terminal 120 switches from grid power to backup power. Conversely, a restoration alert may be transmitted when network terminal 120 switches from backup power to grid power.

NMS 130 may include one or more network devices, or other types of computation or communication devices, that gather, process, search, store, and/or provide information in a manner similar to that described herein. For example, NMS 130 may include a server device that stores software or logic associated with an outage and restoration notification application (hereinafter referred to as “O&R application”) that performs operations associated with remote power outage detection and restoration. NMS 130 may detect, retrieve, and/or process alerts received from network terminal 120 in order to detect an outage, determine that an outage event has occurred, isolate faults and/or locations associated with an outage, and/or detect when power has been restored and/or an outage event has been remedied.

In one exemplary implementation, NMS 130 may detect a power outage and may provide an outage indication to PPES 135. For example, NMS 130 may receive, from network terminal 120, an outage alert indicating that network terminal 120 is operating on battery power (e.g., instead of electrical power from a power grid). The outage indication may include information associated with network terminal 120 (e.g., a device identifier, a network address, etc.) and/or a power state associated with network terminal 120 (e.g., operating on battery power, remaining battery capacity, a time period before the battery is dead, etc.). The O&R application of NMS 130 may record a time associated with the receipt of outage alert and may determine a location (e.g., such as a physical address, coordinates, etc.) that corresponds to the information associated with network terminal 120 (e.g., based on a look-up operation).

In one implementation, the O&R application may generate a hash value (e.g., an encryption based on a particular algorithm) of the physical address of network terminal 120. The hash value may be generated by applying a cryptographic hash function to the network terminal physical address in a standardized format (e.g., a particular order of apartment/suite no., street no., street name, city, state, etc.). In one implementation, the hash function may provide a unique identifier for the physical address without allowing reverse calculations to determine the physical address.

NMS 130 may send an outage indication to PPES 135. The outage indication may include information associated with the outage. The information associated with the outage may include, for example, the recorded time, a hash value based on the physical address of network terminal 120, and/or other information associated with network terminal 120.

In another example, the O&R application of NMS 130 may determine whether an outage event has occurred. For example, the O&R application may store the information associated with the outage in an outage event data structure that includes information associated with other outages detected within a geographical area. The O&R application may, in one example, determine that an outage event has occurred when a quantity of outages (e.g., based on the outage and the other outages) is greater than a threshold. In another example, the O&R application may determine that an outage event has been detected when the outage occurred at approximately the same point in time (e.g., simultaneously) as one or more other outages. In yet another example, the O&R application may determine that an outage event has been detected when the outage occurred at approximately the same location (e.g., within a particular proximity, distance, radius, etc.) as one or more other outages. In still another example, the O&R application may identify outage patterns based on location, timing, and/or quantity of outages relative to the components associated with the power grid (e.g., utility equipment), which may permit faults (e.g., transmission line breaks, equipment failures, etc.) to be located and/or isolated. Based on a determination that an outage event has occurred, NMS 130 may send an outage event indication to PPES 135.

NMS 130 may generate outage updates and/or identify when an outage and/or outage event has been remedied. For example, NMS 130 may receive a restoration alert from network terminal 120 when power has been restored to network terminal 120. The O&R application may process the restoration alert and may provide a restoration notification to PPES 135 indicating that an outage, associated with network terminal 120 (e.g., at a particular location, address, etc.), has been remedied. In another example, the O&R application may provide an outage event update notification that identifies a quantity of outages and/or restorations, locations of outages and/or restorations, and/or trends associated with outages and/or restorations (e.g., whether the quantity of outages are increasing, decreasing, etc.). The O&R application may send a customer notification to network terminal 120 indicating that the outage alert has been received and/or that the power has been restored, etc.

PPES 135 may include one or more network devices, or other types of computation or communication devices, that gather, process, search, store, and/or provide information in a manner similar to that described herein. For example, PPES 135 may include a server device that stores software or logic associated with a look-up application that associates an outage or restoration indication with particular power provider equipment. PPES 135 may include a table of hash values for addresses associated with particular power provider equipment. Each hash value may be generated based on an address (e.g., an address in the same standardized format as used by NMS 130) of premises served by the particular power provider equipment. In one implementation, multiple hash values (and corresponding premises) may be associated with a single piece of power provider equipment.

PPES 135 may receive an outage indication from NMS 130 and perform look-up operations to match the hash value from the outage/restoration indication with a hash value for particular power provider equipment. In another implementation, PPES 135 may receive an outage/restoration event indication with multiple hash values to match to power provider equipment. Based on the hash values in the indication, PPES 1135 may identify power provider equipment that is associated with the physical address of an outage/restoration. However, actual customer addresses for network terminal 120 may not be exchanged between OMS 130 and PPES 135.

In one implementation, PPES 135 may also process information from NMS 130 to compile outage indications, identify nuisance (false-positive) indications, or identify trends. For example, PPES 135 may include an O&R application to perform functions similar to the location-based functions of the O&R application described above with respect to NMS 130. The O&R application residing on PPES 135 may perform location based queries and processing based on the identified power provider equipment and/or physical addresses corresponding to the identified power provider equipment.

Based on an outage indication from NMS 130 and/or subsequent determinations by PPES 135, PPES 135 may send an outage event notification to O&RS 140 to report that an outage event may have been detected. The outage event notification may include, for example, timing information originating from network terminal 120, the particular power provider equipment determined from the matching hash values, a notification type (e.g., a code indicating an outage or restoration notification), and/or summary information.

O&RS 140 may include one or more network devices, or other types of computation or communication devices, that gather, process, search, store, and/or provide information in a manner similar to that described herein. In one implementation, O&RS 140 may include a provider gateway device that may communicate with network 160 and/or one or more PPES 135 on behalf of O&RS 140. O&RS 140 may perform operations associated with outages, outage events, restorations, communications and/or reporting activities associated with public utility commissions, public service commissions, and/or governmental authorities (e.g., local, state, federal authorities, etc.).

O&RS 140 may, for example, receive an outage notification from PPES 135 indicating that an outage has occurred for particular power provider equipment or at a particular location (e.g., based on information associated particular power provider equipment, etc.) within a geographic region. O&RS 140 may, in response to the outage notification, perform operations to isolate a fault associated with the outage, restore power to power provider equipment associated with the outage, and/or cause a maintenance action to be taken to investigate and/or remedy the outage. In another example, O&RS 140 may receive an outage event notification from PPES 135 indicating that an outage event has been detected by NMS 130 (e.g., based on a quantity of outage alerts received from network terminals 120). O&RS 140 may, in response to the outage notification, perform operations to isolate a fault associated with the outage event, restore power to all or a portion of power provider equipment associated with the outage event, and/or cause a maintenance action to be taken to investigate and/or remedy outages associated with the outage event.

In one implementation, O&RS 140 may present location information (e.g., obtained from the outage notification and/or outage event notification) for display via a user interface (UI). The UI may indicate one or more locations, within a geographical area and/or the power grid architecture, at which one or more outages have been reported by PPES 135. O&RS 140 may send information to a maintenance team to enable the maintenance team to remedy the outage. The information, obtained from the outage notification and/or outage event notification, may include a time associated with the outage, a location of power provider equipment associated with the outage, etc. The maintenance team may use the information, for example, to isolate faults within the power grid and/or cause power to be switched or rerouted via transmission paths that do not contain faults. In another example, O&RS 140 may send a notification to government authorities when an outage event may be associated with national security, a man-made disaster, and/or a natural disaster (e.g., when a quantity of outages exceed a particular threshold, etc.).

In yet another example, O&RS 140 may receive a restoration notification, from PPES 135, indicating that power has been restored at a location associated with particular power provider equipment (e.g., based on information associated with hash value) within a geographic region. O&RS 140 may update an outage status associated with the power grid and/or determine a rate at which outages are increasing/decreasing based on the restoration notification. O&RS 140 may, in response to the restoration notification, determine that an outage event has been mitigated and/or remedied. O&RS 140 may send a notification, to public utility commission, a public service commission, governmental authorities, etc., indicating that the outage event has been mitigated and/or remedied. The notification may include information associated with a duration of an outage (e.g., associated with a single network terminal 120), a response time associated with an outage notification, a duration associated with an outage event (e.g., associated with multiple network terminals 120), a quantity of outages detected, information associated with a cause of the outage, etc.

Information server 150 may include one or more server devices, or other types of computation or communication devices, that gather, process, search, store, and/or provide information in a manner similar to that described herein. For example, information server 150 may correspond to an agency (e.g., a local, state, and/or federal authority) from which information associated with weather, natural disasters, national security incidents, and/or conditions associated with a national power grid (e.g., which may affect the power grid associated with O&RS 140) may be obtained. For example, information server 150 may generate and/or send notifications associated with inclement weather which NMS 130, PPES 135, and/or O&RS 140 may use to forecast and/or notify outages. In another example, information server 150 may provide information associated with weather forecasts, historical weather information, and/or historical data associated with energy consumption and/or outages.

Network 160 may include one or more wired and/or wireless networks. For example, network 160 may be include a cellular network, the Public Land Mobile Network (PLMN), and/or a second generation (2G), a third generation (3G), a fourth generation (4G), a fifth generation (5G) and/or another network. Additionally, or alternatively, network 160 may include a wide area network (WAN), a metropolitan area network (MAN), a telephone network (e.g., the Public Switched Telephone Network (PSTN)), an ad hoc network, an intranet, the Internet, a fiber optic-based network (e.g., a fiber optic service (FiOS) network), and/or a combination of these or other types of networks.

In an exemplary operation, PPES 135 may serve as an intermediary between a service provider associated with NMS 130 and a power provider (e.g., utility) associated with O&RS 140. PPES 135 may, for example, receive database excerpts from a service provider, associated with NMS 130, that include network terminal identifiers and hash values based on the physical address of network terminals 120. PPES 135 may also receive database excerpts from a power provider, associated with O&RS 140, that include power provider equipment identifiers and hash values for addresses associated with particular power provider equipment. PPES 135 may use the database excerpts to match corresponding hash values (e.g., of the addresses from the service provider and power provider, respectively) to create a separate reference database for matching network terminal identifiers to power provider equipment identifiers. PPES 135 may receive (e.g., from NMS 130) an outage indication with a particular network terminal identifier, use the reference database identify corresponding power provider equipment, and forward the outage indication (e.g., to O&RS 140) with the power provider equipment identifier (and not the network terminal identifier). Thus, outage information from an network terminal 120 may be reported to the power provider without transferring service provider subscriber information.

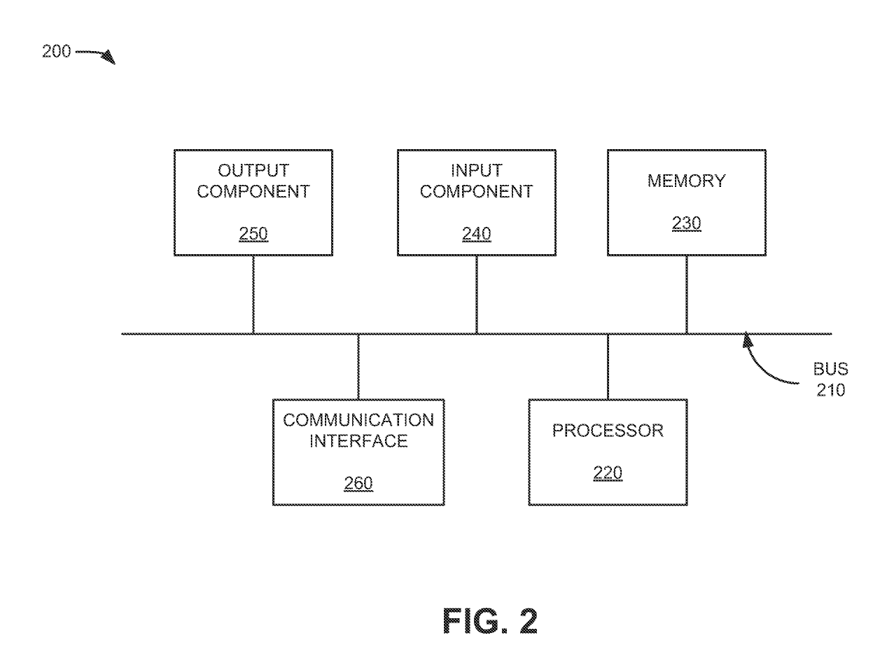

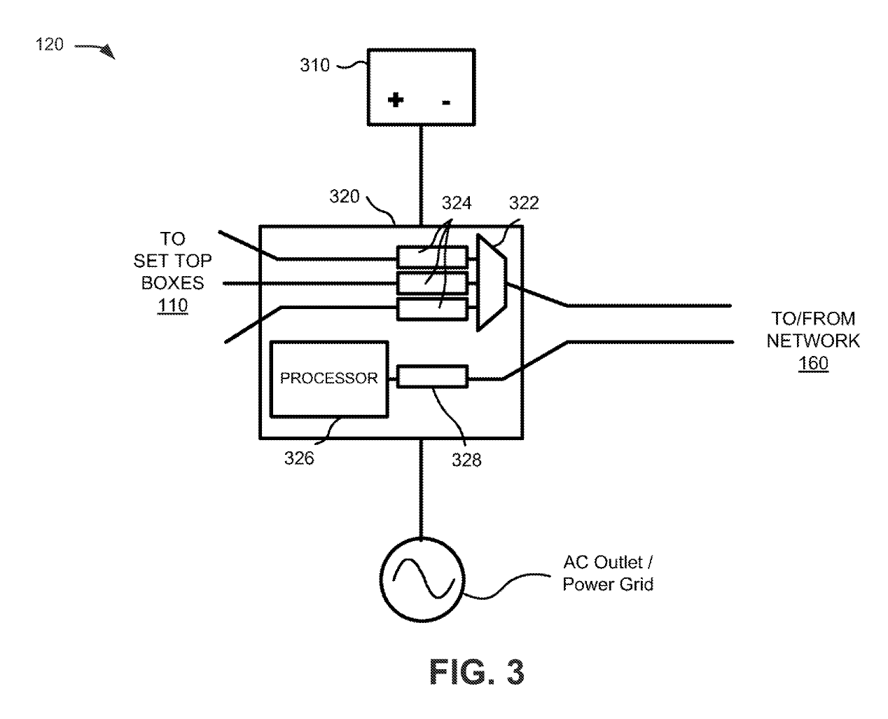

FIG. 2 is a diagram of exemplary components of a device 200. Device 200 may correspond to STB 110, NMS 130, PPES 135, O&RS 140, information server 150, and/or processor 326 (e.g., described below in FIG. 3). Alternatively, STB 110, NMS 130, PPES 135, O&RS 140, information server 150, and/or processor 326, may include one or more devices 200. Device 200 may include a bus 210, a processor 220, a memory 230, an input component 240, an output component 250, and a communication interface 260.

Bus 210 may include a path that permits communication among the components of device 200. Processor 220 may include a processor, microprocessor, or processing logic that may interpret and execute instructions. Memory 230 may include any type of dynamic storage device that may store information and instructions, for execution by processor 220, and/or any type of non-volatile storage device that may store information for use by processor 220.

Input component 240 may include a mechanism that permits a user to input information to device 200, such as a keyboard, a keypad, a button, a switch, etc. Output component 250 may include a mechanism that outputs information to the user, such as a display, a speaker, one or more light emitting diodes (LEDs), etc. Communication interface 260 may include any transceiver-like mechanism that enables device 200 to communicate with other devices and/or systems via wireless communications (e.g., radio frequency, infrared, and/or visual optics, etc.), wired communications (e.g., conductive wire, twisted pair cable, coaxial cable, transmission line, fiber optic cable, and/or waveguide, etc.), or a combination of wireless and wired communications. For example, communication interface 260 may include mechanisms for communicating with another device or system via a network, such as network 160.

As will be described in detail below, device 200 may perform certain operations relating to remote power outage & restoration notification. Device 200 may perform these operations in response to processor 220 executing software instructions contained in a computer-readable medium, such as memory 230. A computer-readable medium may be defined as non-transitory memory device. A memory device may include a space within a single physical memory device or spread across multiple physical memory devices. The software instructions may be read into memory 230 from another computer-readable medium or from another device. The software instructions may be read into memory 230 from another computer-readable medium or from another device. The software instructions contained in memory 230 may cause processor 220 to perform processes described herein. Alternatively, hardwired circuitry may be used in place of or in combination with software instructions to implement processes described herein. Thus, implementations described herein are not limited to any specific combination of hardware circuitry and software.

Although FIG. 2 shows exemplary components of device 200, in other implementations, device 200 may include fewer components, additional components, different components, or differently-arranged components than depicted in FIG. 2. As an example, in some implementations, input component 240 and/or output component 250 may not be implemented by device 200. In these situations, device 200 may be a “headless” device that does not explicitly include an input or an output device. Additionally, or alternatively, one or more components of device 200 may perform one or more tasks described as being performed by one or more other components of device 200.

FIG. 3 is a diagram of exemplary functional components that may be associated with network terminal 120. As illustrated, network terminal 120 may include a storage component 310 and a communication component 320. The functional components in FIG. 3 may be implemented using one or more of the components of device 200 (FIG. 2), such as processor 220.

Storage component 310 may include one or more devices that can store electrical power. In one implementation, storage component 310 may be a battery that is capable of storing electrical power for use by network terminal 120. For example, during an outage (e.g., when AC power from a power grid is disrupted), network terminal 120 may continue to operate for a period of time (e.g., 1 hour, 4 hours, 8, hours, 12 hours, etc.) using the electrical power stored in storage component 310. Network terminal 120 may rely on storage device 310 to continue to operate until the outage is remedied (e.g., when AC power is restored) or until the stored power, within storage component 310, dissipates (e.g., when a quantity of charge is less than a threshold). Storage component 310 may be charged when the AC power is restored.

Communication component 320 may permit network terminal 120 to communicate with network 160 and/or STB 110 and may be connected to power sources (e.g., storage component 310 and/or an AC outlet via which AC power is received from a power grid). Communication component 320 may include a demultiplexer 322, a receiver 324, and/or a processor 326. Demultiplexer 322 may include a device that receives an incoming signal comprising multiple wavelengths and spatially separates the component wavelengths of the received signal, such that there are a number of separate outgoing signals at each component wavelength. In one example implementation, demultiplexer 322 may receive a multi-wavelength optical signal from network 160 and may send outgoing signals, at component wavelengths, to receivers 324. In another exemplary implementation, demultiplexer 322 may receive a multi-wavelength radio frequency (RF) signal from network 160 and may send outgoing signals, at component wavelengths, to receivers 324.

Receiver 324 may include one or more devices that receive an incoming signal and use the incoming signal to generate an outgoing modulated signal. In one exemplary implementation, receiver 324 may be a charged coupled device and/or photodetector. In another exemplary implementation receiver 324 may be a device that receives wired and/or wireless signals. In one exemplary implementation, a bank of receivers 324 may receive a number of incoming signals from demultiplexer 322 and may generate corresponding modulated signals (e.g., video, voice, data, etc.) for transmission to one or more STBs 110 or telephone lines.

Processor 326 may include a processor, a microprocessor, or some form of hardware logic (e.g., an application specific integrated circuit (ASIC) or a field programmable gate array (FPGA)). In one exemplary implementation, processor 326 may control the manner in which network terminal 120 receives power. For example, in a default mode, processor 326 may cause network terminal 120 to operate based on electrical power (e.g., AC power) received, via an A/C outlet from a power grid. Processor 326 may monitor the state of charge associated with storage component 310 and may cause a portion of the AC power to be used to charge storage device 310. Processor 326 may detect when AC power is no longer being received and may cause communication component 320 to begin receiving power form storage component 310. Based on the detection that AC power is no longer being received, processor 326 may send an outage alert, via transmitter 328 and to NMS 130, indicating that a potential outage has occurred. The outage alert may include an indicator associated with an outage, a time associated with the outage, a state of charge associated with storage device 310, and/or information associated with network terminal 120 (e.g., a device identifier, an network address, etc.).

Processor 326 may detect when AC power has been restored and may cause communication component 320 to begin receiving power from the AC outlet (or from a DC transformer connected to the AC outlet). Based on the detection that AC power has been restored, processor 326 may send a restore notification, via transmitter 328, to NMS 130. The restore notification may include an indicator that AC power has been restored, a time that the AC power was restored, a state of charge associated with storage device 310, and/or information associated with network terminal 120. Processor 326 may send a status message (e.g., periodically, at particular times of the day, randomly, etc.) indicating a state of health of network terminal 120, a state of charge of storage device 310, and/or an indication associated with a current power source.

Transmitter 328 may include one or more devices that transmit a wired and/or wireless signal to network 160. In one exemplary implementation, transmitter 328 may include a laser, which may generate and transmit an optical signal at a particular wavelength and/or with a particular bandwidth. In another exemplary implementation, transmitter 328 may be a device that transmits a wired and/or wireless signal at a particular wavelength and/or bandwidth. Transmitter 328 may receive a signal from processor 326 and may use the received signal to modulate and/or generate another signal at a given wavelength and/or bandwidth to be transmitted to network 160.

The functional components, illustrated in FIG. 3, are provided for explanatory purposes only. In practice, network terminal 120 may include fewer functional components, additional functional components, different functional components, or differently-arranged functional components than the ones described with respect to FIG. 3. Additionally, one or more functional components in FIG. 3 may perform one or more functions described as being performed by another one or more of the functional components of FIG. 3.

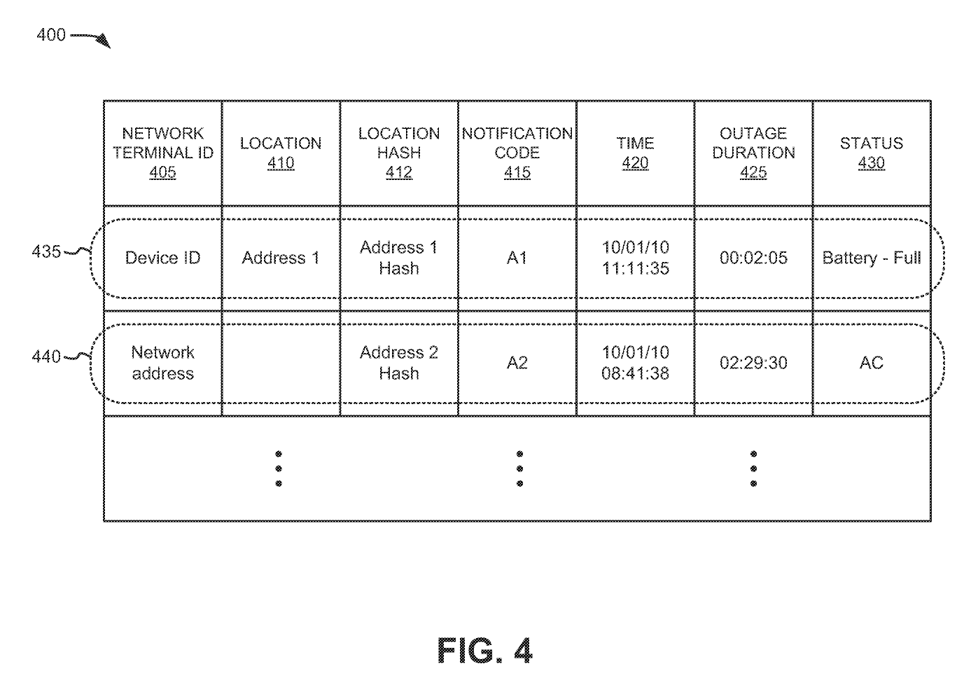

FIG. 4 is a diagram of an exemplary outage indication data structure 400 (hereinafter referred to as “data structure 400”) according to an implementation described herein. In one exemplary implementation, one or more data structures 400 may be stored in a storage device included as part of memory 330 of NMS 130. In another implementation, a different data structure 400 may be stored for each geographic region with which NMS 130 is associated. In another exemplary implementation, data structure 400 may be stored in a memory associated with another device or a group of devices, separate from or including memory 330 of NMS 130.

As shown in FIG. 4, data structure 400 may include a collection of fields, such as a network terminal identifier (ID) field 405, a location field 410, a location hash field 412, a notification code field 415, a time field 420, an outage duration field 425, and a status field 430. Although FIG. 4 shows exemplary fields of data structure 400, in other implementations, data structure 400 may contain fewer fields, different fields, additional fields, or differently-arranged fields than depicted in FIG. 4. Additionally, or alternatively, one or more fields of data structure 400 may include information described as being included in one or more other fields of data structure 400.

Network terminal ID field 405 may store information associated with a particular network terminal 120 from which an outage alert was received. The information associated with the particular network terminal 120 may include an identifier associated with network terminal 120 (e.g., a coder-decoder (CODEC), an electronic serial number, a network address, etc.). Location field 410 may store information associated with a location of the particular network terminal 120. For example, the O&R application may perform a look-up operation by identifying information associated with network terminal 120 (e.g., stored in a memory associated with NMS 130) that matches information, associated with the particular network terminal 120, received in an outage alert. The O&R application may retrieve, from the memory, location information that corresponds to the stored information associated with network terminal 120 and may store the location information in location field 410. The location information may include a physical address associated with a user of STB 110 that is coupled to the particular network terminal 120. The physical address may be included in a standardized format (e.g., that is consistent with a format used in field 610 of data structure 600 described below). In other implementations, the location information may include grid coordinates, latitude and/or longitude, etc. In still other implementations, location field 410 may be omitted.

Location hash field 412 may store a non-reversable hash value of a physical address of a corresponding device identified in network terminal ID field 405. In one implementation, the location hash may be generated directly from information in corresponding location field 410. For example, the O&R application may generate the hash value by applying a cryptographic hash function, such as the Secure Hash Algorithm (SHA)-1 or MD5 algorithm, to the physical address in field 410. In another implementation, the O&R application may retrieve, from the memory, a hash value that corresponds to the physical address associated with network terminal 120 and may store the hash value in location hash field 412.

Notification code field 415 may store information (e.g., an alarm code, a string, a value, a label, etc.) associated with a type of alert or indication received from the particular network terminal 120. For example, the O&R application may store an indication that an outage has been detected. In another example, the O&R application may store an indication that power has been restored. In yet another example, the O&R application may store indications associated with a charge state of storage device 310 (FIG. 3). Time field 420 may store a time associated with a point in time that an outage was detected by the particular network terminal 120. In another example, the O&R application may store another point in time when the outage alert was received from the particular network terminal 120. Outage duration field 425 may store a value associated with an elapsed time since the outage was detected (e.g., or that the outage alert was received) by the particular network terminal 120. Status field 430 may store an indication regarding whether the particular network terminal 120 is operating based on battery power, AC power, and/or regarding a battery charge state.

For example, NMS 130 may receive an outage alert from the particular network terminal 120 and the O&R application may store, in data structure 400, information associated with the particular network terminal 120 (e.g., device ID) obtained from the outage alert and a physical address associated with the particular network terminal 120 (e.g., address 1) obtained as a result of a look-up operation (e.g., as shown by outline 435). The O&R application may calculate a hash value (e.g., address 1 hash) based on the physical address. Alternatively, or additionally, the O&R application may store an indication that an outage has been detected (e.g., A1), a point in time that the outage was detected (e.g., Oct. 1, 2010, 11:01:35), an elapsed time since the point in time that the outage was detected (e.g., 00:02:05), and a status associated with the power state and/or charge state of the device (e.g., Battery-Full) (e.g., as shown by outline 435).

In another example, NMS 130 may receive a restore alert from the particular network terminal 120 and the O&R application may store, in data structure 400, information associated with the particular network terminal 120 (e.g., a network address) obtained from the restore alert and a hash value for a physical address (e.g., Address 2 Hash) associated with the particular network terminal 120 obtained as a result of another look-up operation (e.g., as shown by outline 440). In this example, the actual physical address associated with the particular network terminal 120 may not be included in data structure 400. Alternatively, or additionally, the O&R application may store an indication that AC power has been restored (e.g., A2), a point in time that the power was restored (e.g., Oct. 1, 2010, 08:41:38), an elapsed time of the outage (e.g., 02:29:30), and a status associated with the power state and/or charge state of the device (e.g., AC, Battery-medium) (e.g., as shown by outline 440).

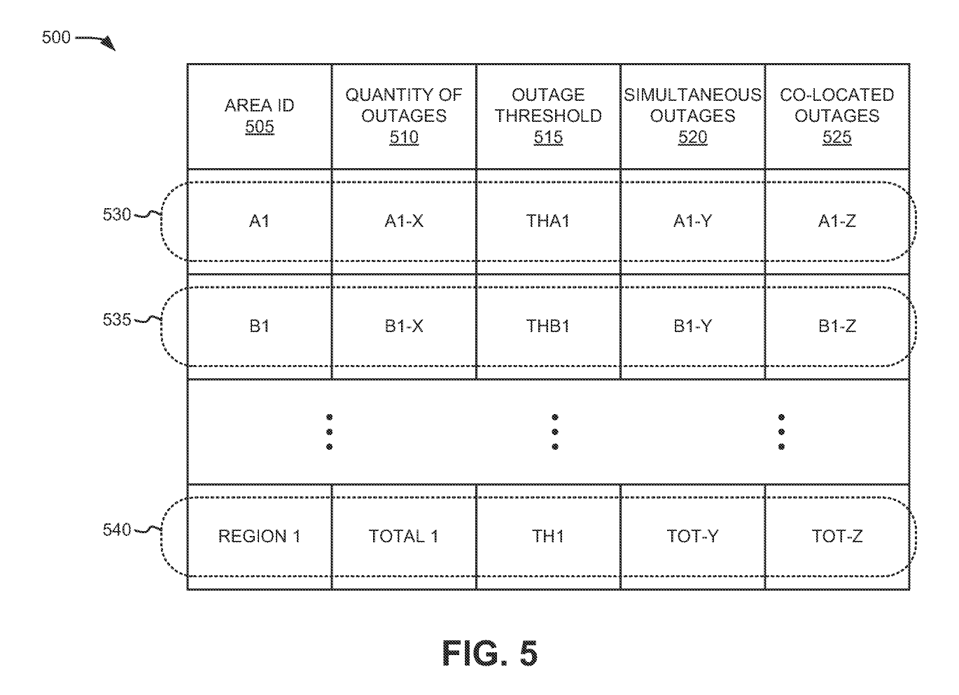

FIG. 5 is a diagram of an exemplary outage event data structure 500 (hereinafter referred to as “event data structure 500”) according to an implementation described herein. In one exemplary implementation, one or more event data structures 500 may be stored in a storage device included as part of memory 330 of NMS 130. In another exemplary implementation, event data structure 500 may be stored in a memory associated with another device or a group of devices, separate from or including memory 330 of NMS 130.

As shown in FIG. 5, event data structure 500 may include a collection of fields, such as an area identifier (ID) field 505, a quantity of outages field 510, an outage threshold field 515, a simultaneous outages field 520, and a co-located outages field 525. Although FIG. 5 shows exemplary fields of event data structure 500, in other implementations, event data structure 500 may contain fewer fields, different fields, additional fields, or differently-arranged fields than depicted in FIG. 5. Additionally, or alternatively, one or more fields of event data structure 500 may include information described as being included in one or more other fields of data structure 500.

Area identifier (ID) field 505 may store an identifier associated with a particular geographical area in which network terminals 120 are located. Quantity of outages field 510 may indicate a number/quantity of outages associated with the particular geographical area within a period of time. Outage threshold field 515 may store a value that is used by the O&R application to determine whether an outage event, associated with the particular geographical area, is triggered. For example, the outage event for the particular geographical area may be triggered based on a determination that a quantity of the outages is greater than the value. Simultaneous outages field 520 may store a quantity of simultaneous outages associated with a quantity of network terminals 120, within the particular geographical area, that detect an outage at approximately the same time (e.g., within a particular period of time). Co-located outages field 525 may store a quantity of co-located outages associated with a quantity of network terminals 120, within the particular geographical area, that detect an outage at approximately the same location (e.g., within a particular distance, radius, or area).

For example, the O&R application may retrieve a data outage data structure (e.g., data structure 400 of FIG. 4) associated with a particular geographic area (e.g., A1) and may determine a quantity of outages (e.g., A1-X) detected by network terminals 120 that are located within the particular geographical area (e.g., as shown by outline 530). The quantity of outages may be determined from a prior point in time to a current time. The O&R application may, for example, identify a quantity of simultaneous outages (e.g., A1-Y) within the particular geographical area based on whether the outages were detected at approximately the same time (e.g., from time field 420 of FIG. 4) (e.g., as shown by outline 530). The O&R application may, in another example, identify a quantity of co-located outages (e.g., A1-Z) within the particular geographical area based on whether the outages were detected at approximately the same location (e.g., from location field 410 of FIG. 4) (e.g., as shown by outline 530).

The O&R application may use event data structure 500 to determine whether an outage event has been triggered. For example, the O&R application may compare the quantity of outages (e.g., A1-X) with an outage threshold (e.g., THA1) to determine whether the quantity of outages is greater than the outage threshold. Based on a determination that the quantity of outages is greater than the outage threshold, the O&R application may send an outage event indication to PPES 135/O&RS 140 alerting a power provider (e.g., associated with O&RS 140) that an outage event has been triggered. In another example, the O&R application may compare the quantity of simultaneous outages (e.g., A1-Y) to a simultaneous threshold to determine whether an outage event has been triggered. In yet another example, the O&R application may compare a quantity of co-located outages (e.g., A1-Z) to a co-located threshold to determine whether an outage event has been triggered. Based on a determination that an outage event has been triggered (e.g., when the quantity of simultaneous outages is greater than the simultaneous threshold or when the quantity of co-located outages is greater than the co-located threshold), the O&R application may send the event outage indication.

The O&R application may store outage information, in event data structure 500, that was obtained and/or processed from other outage data structures (e.g., data structures 400) associated with other geographic areas within which other network terminals 120 are located (e.g., as shown by outline 535). The O&R application may use the outage information from one or more geographical areas (e.g., as shown by outlines 530, 535, etc.) to generate total outage information for storage in event data structure 500 (e.g., as shown by outline 540). The O&R application may use the total outage information to determine whether an outage event is triggered in a manner similar to that described above and may send an outage event notification to O&RS 140 based on a determination that an outage event has been triggered.

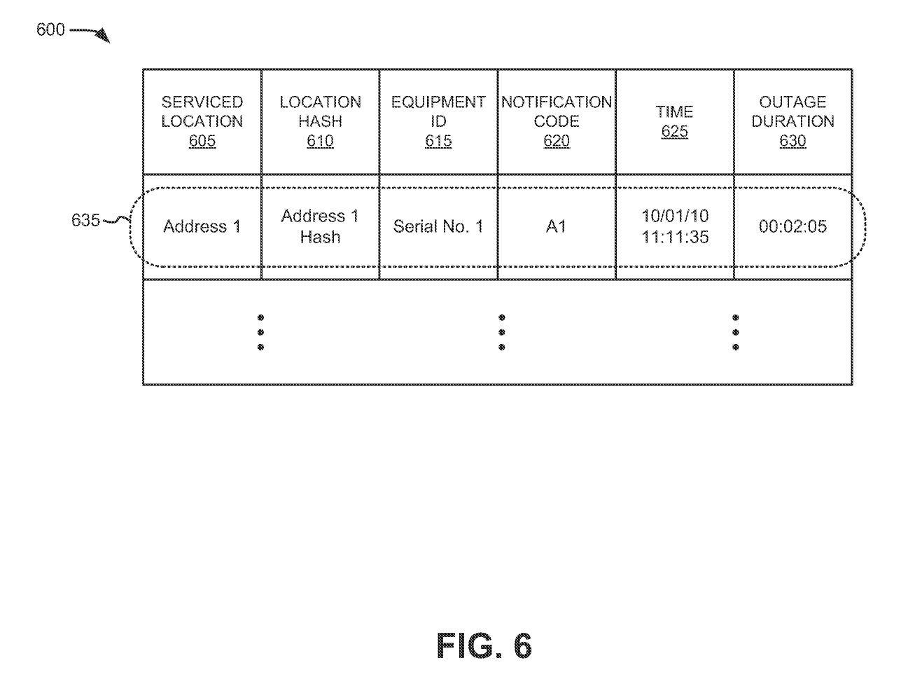

FIG. 6 is a diagram of an exemplary outage notification data structure 600 (hereinafter referred to as “data structure 600”) according to an implementation described herein. In one exemplary implementation, one or more data structures 600 may be stored in a storage device included as part of memory 330 of PPES 135. For example, a different data structure 600 may be stored for each geographic region with which PPES 135 is associated. In another exemplary implementation, data structure 600 may be stored in a memory associated with another device or a group of devices, separate from or including memory 330 of PPES 135.

As shown in FIG. 6, data structure 600 may include a collection of fields, such as a serviced location field 605, a location hash field 610, an equipment identification (ID) field 615, a notification code field 620, a time field 625, and an outage duration field 630. Although FIG. 6 shows exemplary fields of data structure 600, in other implementations, data structure 600 may contain fewer fields, different fields, additional fields, or differently-arranged fields than depicted in FIG. 6. Additionally, or alternatively, one or more fields of data structure 600 may include information described as being included in one or more other fields of data structure 600.

Serviced location field 605 may store information associated with a location of a particular customer of a power provider. The location information may include a physical address associated with a customer of the power provider. The physical address may be included in a standardized format (e.g., that is consistent with a format used in location field 410 of data structure 400 described above). In other implementations, serviced location field 605 may be omitted.

Location hash field 610 may store a hash value of a physical address of a corresponding location identified in serviced location 605. In one implementation, location hash field 610 may be generated directly from information in corresponding location field 605 using the same cryptographic hash function used by the O&R algorithm for location hash field 412 of data structure 400.

Equipment ID field 615 may store information associated with particular power provider equipment (e.g., a particular substation, transmission line, transformer, etc.). The information associated with the particular power provider equipment may include a serial number, proprietary code, grid address, etc. associated with the particular power provider equipment. Generally, the values in equipment ID field 615 may be any combination of physical or logical (e.g. circuit identifier) tags that would be meaningful for power provider operations teams.

Notification code field 620, time field 625, and outage duration field 630 may be populated with information from outage indications received from NMS 130. The look-up application in PPES 135 may receive an outage/restoration indication with a particular location hash value (e.g., from location hash field 412). The look-up application may identify an identical hash value in location hash field 610 of data structure 600. PPES 135 may then populate notification code field 620, time field 625, and outage duration field 630 with information from the received outage indication. Notification code field 620 may include the same information (for a particular hash value) stored in notification code field 415 of data structure 400. Time field 625 may include the same information (for the particular hash value) stored in time field 420 of data structure 400. Outage duration field 630 may include the same information (for the particular hash value) stored in outage duration field 425 of data structure 400.

For example, PPES 135 may receive an outage indication from NMS 130. The outage indication may include a hash location (e.g., from hash location field 412) and outage information for the location (e.g., information from one or more of notification code field 415, time field 420, and outage duration field 425). PPES 135 may perform a look-up operation based on the received hash location to determine a corresponding equipment identifier. For example, the look-up application may perform a look-up operation by identifying a hash value (e.g., address 1 hash) associated with a serial number for power provider equipment (e.g., stored in a memory associated with PPES 135) that matches the hash value included in the outage indication (e.g., as shown by outline 635). The look-up application may retrieve, from the memory, the equipment identifier (e.g., serial no. 1) and serviced location (e.g., address 1) that corresponds to the stored information associated with the location hash and may store the equipment identifier and serviced address in location hash field 610 (e.g., as also shown by outline 635). The look-up application may also populate additional fields corresponding to the hash value with outage information from the outage indication. Thus, as further shown in outline 635, particular outage information from notification code field 415, time field 420, and outage duration field 425 may be populated in notification code field 620 (e.g., A1), time field 625 (e.g., 10/01/10, 11:11:35), and outage duration field 630 (e.g., 00:02:05).

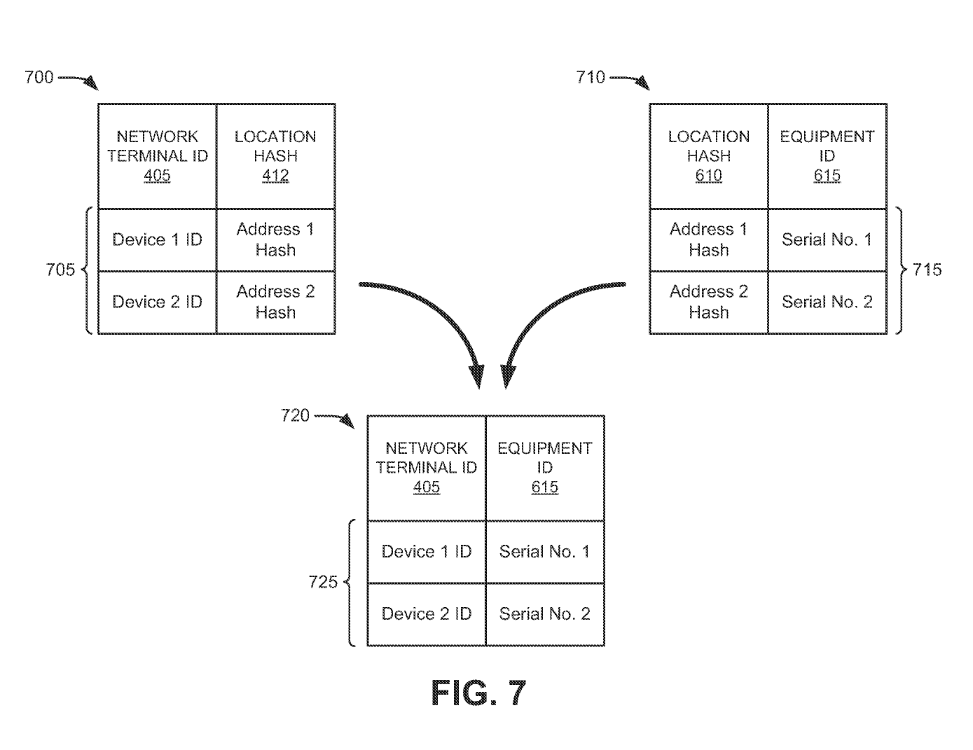

FIG. 7 is a diagram of an exemplary correlation process that may be performed by PPES 135, according to an implementation described herein. A service provider database excerpt 700 may be provided to PPES 135 by a service provider (e.g., via NMS 130 or another device). Service provider database excerpt 700 may include, for example, network terminal ID field 405, location hash field 412, and a variety of entries 705 corresponding to all (or a subset of) network terminals 120 associated with the service provider. Similarly, a power provider database excerpt 710 may be provided to PPES 135 by a power provider (e.g., via O&RS 140 or another device). Power provider database excerpt 710 may include, for example, location hash field 605, equipment ID field 615, and a variety of entries 715 corresponding to all (or a subset of) power provider equipment associated with the power provider.

PPES 135 may use the database excerpts 700 and 710 to match corresponding hash values (e.g., from location hash field 412 and location hash field 605) to create a separate reference database 720. Reference database 720 may include, for example, network terminal ID field 405, equipment ID field 615, and a variety of entries 725. Thus, PPES 135 may use reference database 720 for matching network terminal identifiers to power provider equipment identifiers. In one implementation, PPES 135 may generate/update reference database 720 on a periodic basis (e.g., weekly, monthly, etc.) using updated database excerpts 700 and 710.

In one exemplary implementation, one or more databases720 may be stored in a storage device included as part of memory 330 of PPES 135. For example, a different database 720 may be stored for each geographic region with which PPES 135 is associated. In another exemplary implementation, database 720 may be stored in a memory associated with another device or a group of devices, separate from or including memory 330 of PPES 135

In operation, PPES 135 may receive (e.g., from NMS 130) an outage indication with a particular network terminal identifier. PPES 135 may match the network terminal identifier to field 405 of reference database 720 and identify corresponding power provider equipment from equipment ID field 615. PPES 135 may then forward the outage indication to the power provider (e.g., to O&RS 140) with the power provider equipment identifier and not the network terminal identifier.

In an exemplary implementation, PPES 135 is hosted by a third party, independent from both the service provider and the power provider. Database excerpts 700 and 710 are calculated by the service provider and the power provider respectively and sent to the third party. Database excerpts 700 and 710 may include location hashes (e.g., from fields 412 and 610, respectively) but no clear-text (e.g., unencrypted) location addresses. Thus, the third party cannot determine the physical location of the service provider end customers or the power provider end customers. The use of the location hashes protects the identity and thus the privacy of both the service provider subscriber and the power provider customer relative to the third party. PPES 135 may use reference database 720 to match network terminal identifiers (e.g., from field 405) to power provider equipment identifiers (e.g., from field 615). In one implementation, as long as care is taken to ensure that one power provider equipment identifier does not identify a unique power provider customer address, the power provider cannot determine the exact identity of the service provider customer. In one implementation, for example, network managers could make sure that each power provider equipment identifier supports at least a certain minimum number (e.g., 4, 8, 12, etc. . . . ) of users. This allows the service provider to protect the identity and thus the privacy of their end customers while sharing power alerts with the power provider. Likewise, the service provider does not have access to excerpt databases 710 and 720 and thus does not receive any information concerning the power provider customers.

In another exemplary implementation, PPES 135 may be hosted by the service provider who receives excerpt database 710 from the service provider and computes reference database 720. In this implementation, the physical address of the power provider end customer may be hashed or not. When an alert in the service provider network is detected, PPES 135 may identify the power provider equipment identifier matching the network terminal 120 responsible for the alert. PPES 135 may then forward an outage notification to the power provider with the power provider equipment identifier and not the network terminal identifier. As in the previous implementation, as long as care is taken to ensure that one power provider equipment identifier does not identify a unique power provider customer address, the power provider cannot determine the exact identity of the service provider subscriber. In one implementation, for example. a network manager could make sure that each power provider equipment identifier supports at least a certain minimum number (e.g., 4, 8, 12, etc. . . . ) of users. This allows the service provider to protect the identity and thus the privacy of their end customers while sharing power alerts with the power provider. In this implementation where PPES 135 is hosted by the service provider, however, the identity of power provider customers affected by the power outage could be inferred by the service provider.

In another exemplary implementation, the power provider equipment identifier (e.g., in field 615) can be replaced or supplemented by other physical (e.g., other equipment identifiers) or logical (e.g., circuit identifier) tags. These tags can be more meaningful to the power provider's operation team and facilitate faster restoration. In this implementation, database excerpt 710 may contain more than one column associated with a specific location hash. Likewise, reference database 720 may contain more than one power provider tag (e.g., equipment identifier, circuit identifier, etc. in field 615 or additional fields). As long as the combination of all power provider tags does not identify a unique end user, the power provider cannot infer the identity of the service provider subscriber.

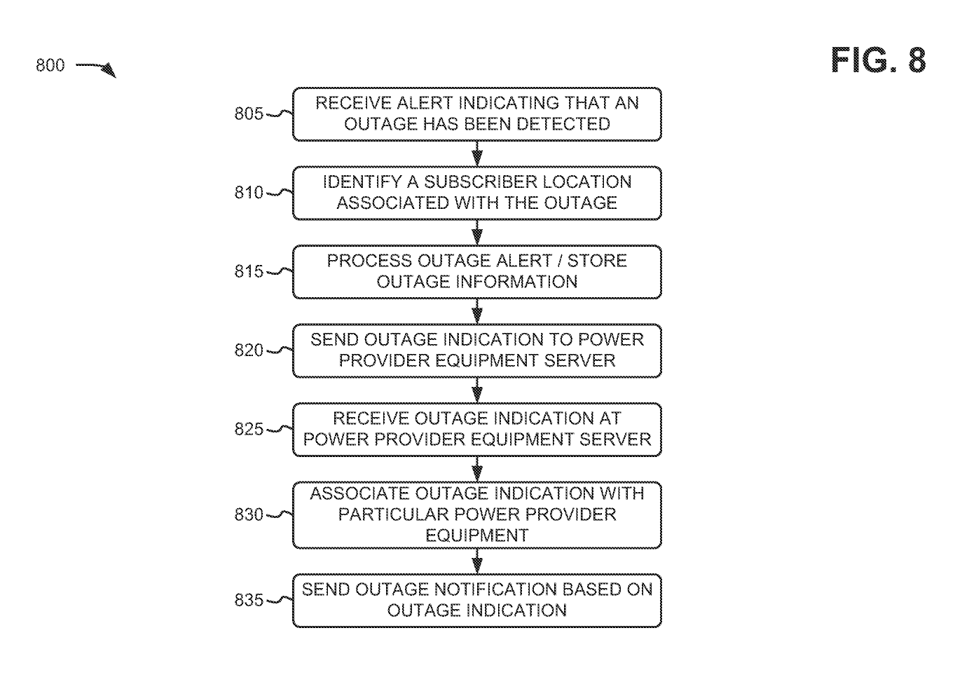

FIG. 8 is a flowchart of an exemplary process 800 for detecting and notifying an outage/restoration according to an implementation described herein. In one exemplary implementation, process 800 may be performed by NMS 130 and PPES 135. In another implementation, some or all of process 800 may be performed by a device or collection of devices separate from, or in combination with, NMS 130 and PPES 135—for example O&RS 140.

As shown in FIG. 8, process 800 may include receiving an alert that an outage has been detected (block 805). For example, network terminal 120 may detect an outage when AC power is no longer being received. Based on the detection of the outage, network terminal 120 may switch power sources from the AC power to storage device 310. Network terminal 120 may generate an outage alert and may send the outage alert to NMS 130. The outage alert may include information associated with network terminal 120 (e.g., a device identifier, a network address, etc.), an indication that an outage has been detected, a time that the outage was detected, a charge state associated with storage device 310, and/or an indication that network terminal 120 is operating on stored power. NMS 130 may receive the outage alert.

As also shown in FIG. 8, process 800 may include identifying a subscriber location associated with the outage (block 810). For example, the O&R application, hosted by NMS 130, may perform a look-up operation by comparing the information associated with network terminal 120 received in the outage alert to information associated with network terminals 120 stored in a memory associated with NMS 130. The O&R application may identify information, associated with network terminal 120 and stored in the memory, that matches the received information associated with network terminal 120 and may retrieve, from the memory, location information, associated with network terminal 120. The location information may, for example, include a physical address associated with a user of STB 110 that is coupled to network terminal 120. In another example, the location information may include coordinates (e.g., grid coordinates, latitude and/or longitude, etc.).

As further shown in FIG. 8, process 800 may include processing an outage alert and/or storing outage information (block 815). For example, the O&R application may generate a hash value based on the location information and store outage information associated with network terminal 120 in an outage data structure (e.g., data structure 400 of FIG. 4). The outage information may include the information associated with network terminal 120, the location information based on the look-up operation, the location hash value, the indication that an outage has been detected, a time associated with the outage (e.g., a time that the outage was detected and/or that the outage alert was received), an elapsed time since the time associated with the outage, a status regarding a power source on which the network terminal 120 is operating and/or a charge state of storage device 310.

Process 800 may also include sending an outage indication to a power provider equipment server (block 820). For example, based on the receipt of the outage alert, the O&R application of NMS 130 may send an outage indication associated with network terminal 120 to PPES 135 that includes all or a portion of the outage information stored in data structure 400. Particularly, the outage indication may include the location hash value but not the location information (e.g., physical address) of network device 120. In another example, the O&R application may send a status message (e.g., periodically, randomly, upon the occurrence of some event, etc.), at a later point in time, that includes all or a portion of the outage information. In yet another example, the O&R application may send a status and/or the outage notification when a number of outage alerts, received from network terminal 120 and/or other network terminals 120, is greater than a threshold.

Process 800 may further include receiving the outage indication at the power provider equipment server (block 825) and associating the outage indication with particular power provider equipment (block 830). For example, PPES 135 may receive the outage indication from NMS 130. Based on the location hash value, PPES 135 may perform a look-up in a power provider equipment table to identify a matching equipment hash value. Assuming a match is found, PPES 135 may store outage information associated with network terminal 120 in an outage notification data structure (e.g., data structure 600 of FIG. 6). The outage information may include the equipment hash value, an identifier for corresponding power provider equipment, a coordinate or an address of a location serviced by the power provider equipment, the indication that an outage has been detected, a time associated with the outage (e.g., a time that the outage was detected and/or that the outage alert was received), an elapsed time since the time associated with the outage, and/or a status regarding a power source on which the network terminal 120 is operating and/or a charge state of storage device 310.

Process 800 may further include sending an outage notification based on the outage indication (block 835). For example, PPES 135 may provide an outage notification to O&RS 140 based on the outage indication from NMS 130. The outage notification may include all or a portion of the outage information stored in data structure 800. Particularly, the outage notification may include outage alert details reported by network device 120 associated with particular power provider equipment, but without connection to a particular subscriber's physical address.

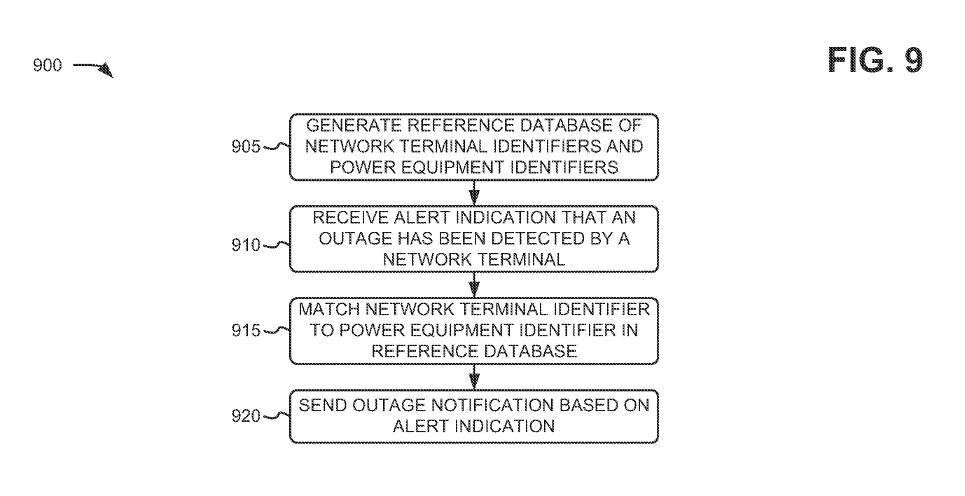

FIG. 9 is a flowchart of another exemplary process 900 for detecting and notifying an outage according to an implementation described herein. In one exemplary implementation, process 900 may be performed by PPES 135. In another implementation, some or all of process 900 may be performed by a device or collection of devices separate from, or in combination with, PPES 135—for example NMS 130 and/or O&RS 140.

As shown in FIG. 9, process 900 may include generating a reference database of network terminal identifiers and power equipment identifiers (block 905). For example, referring to FIG. 7, PPES 135 may receive database excerpt 700 from a service provider and database excerpt 710 from a power provider that each include hash values of addresses (e.g., associated with service provider subscribers and power provider equipment, respectively). PPES 135 may match the corresponding hash values to create a separate reference database 720. Reference database 720 may include, for example, network terminal ID field 405, equipment ID field 615, and a variety of entries 725.

Process 900 may also include receiving an alert indication that an outage has been detected by a network terminal (block 910). For example, network terminal 120 may detect an outage when AC power is no longer being received. Network terminal 120 may generate an outage alert and may send the outage alert to NMS 130. The outage alert may include information associated with network terminal 120 (e.g., a device identifier, a network address, etc.), an indication that an outage has been detected, a time that the outage was detected, a charge state associated with storage device 310, and/or an indication that network terminal 120 is operating on stored power. NMS 130 may receive the outage alert and may forward some or all of the information in the outage alert to PPES 135.

As also shown in FIG. 9, process 900 may include matching a network terminal identifier to a power equipment identifier in the reference database (block 915), and sending an outage notification based on the alert indication (block 920). For example, referring to FIG. 7, PPES 135 may match the network terminal identifier to field 405 of reference database 720 and identify a corresponding power provider equipment identifier from equipment ID field 615. PPES 135 may forward an outage notification to the power provider (e.g., to O&RS 140), so that the notification includes the power provider equipment identifier and not the network terminal identifier.

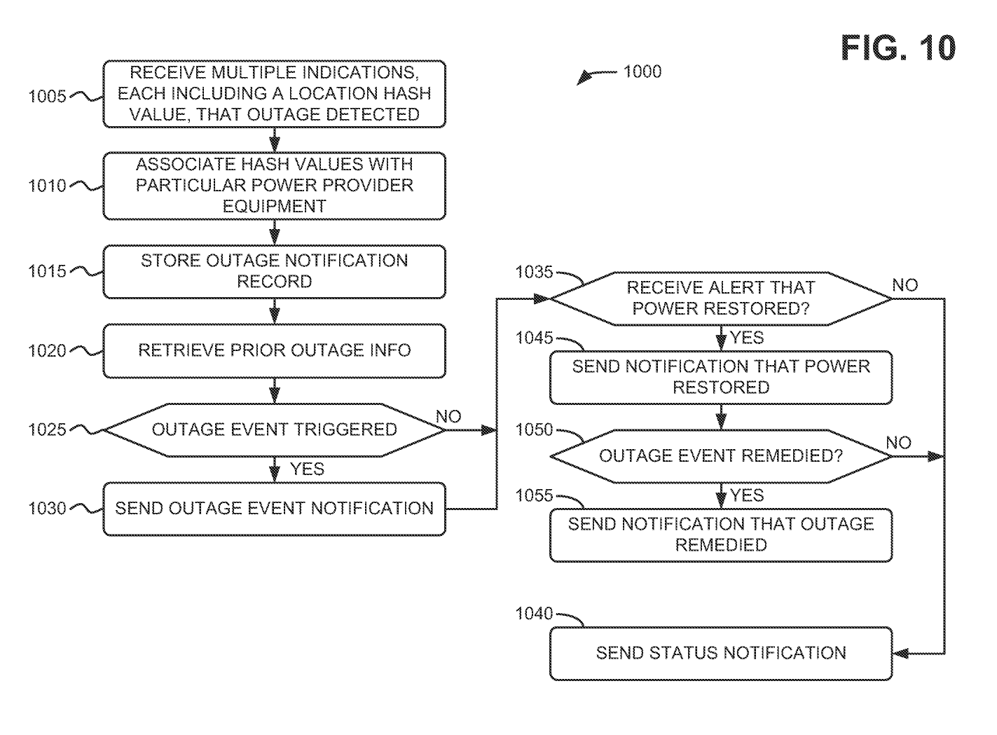

FIG. 10 is a flowchart of an exemplary process 1000 for detecting and notifying an outage/restoration event according to an implementation described herein. In one exemplary implementation, process 1000 may be performed by PPES 135. In another implementation, some or all of process 1000 may be performed by a device or collection of devices separate from, or in combination with, PPES 135—for example NMS 130 and/or O&RS 140.

As shown in FIG. 10, process 1000 may include receiving multiple outage indications, each including a location hash value, that an outage has been detected (block 1005). For example, NMS 130 may receive outage alerts from multiple network terminals 120, process the outage alerts, and forward the processed outage alerts to PPES 135 as outage indications. The outage indications may each include a location hash value based on a physical address associated with each network terminal 120.

Process 1000 may further include associating a hash value from each of the outage indications with particular power provider equipment (block 1010) and storing each of the outage indications with the particular power provider equipment as an outage notification record (block 1015). For example, PPES 135 may perform a look-up in a power provider equipment table to identify a matching equipment hash value for each location hash value. PPES 135 may match each equipment hash value to an equipment identifier (e.g., serial number) and to the corresponding outage indication data. PPES 135 may store the equipment identifier and the corresponding outage indication data in a memory (e.g., data structure 600).

As further shown in FIG. 10, process 1000 may include retrieving prior outage information (block 1020). For example, an O&R application associated with PPES 135 may retrieve, from a memory, outage information associated with network terminals 120 (hereinafter referred to as outage event information) within one or more geographic regions within which network terminals 120 are located. In one example, the outage event information may be obtained from an outage event data structure (e.g., event data structure 500 of FIG. 5). The outage event information may include information associated with a geographic area (e.g., an area ID) from which prior outages have been detected, a quantity of outages associated with the geographical area, an outage threshold, a quantity of simultaneous outages within the geographic area, a quantity of co-located outages in the geographic area, and/or other outage event information (e.g., such as outage trends, etc.). The prior outages may, for example, be associated with outages that occurred within a particular period of time (e.g., 5 minutes, 30 minutes, one hour, two hours, 12 hours, etc.).

As also shown in FIG. 10, if an outage event is triggered (block 1025—YES), then process 1000 may include sending an outage event notification (block 1030). For example, PPES 130 may determine that an outage event, associated with the geographic area has occurred when the quantity of outages is greater than the outage threshold. In another example, PPES 130 may determine that an outage event has occurred when a pattern of outages are detected, such as a quantity of simultaneous outages (e.g., greater than a simultaneous threshold), co-located outages (e.g., an outage that occurs at a distance and/or area that is less than a location threshold relative to another outage). In this example, PPES 135 may detect the outage event when a quantity of simultaneous outages (and/or co-located outages) is detected. The quantity of simultaneous outage may correspond to the quantity of network terminals 120 located on a particular street, connected to a particular substation, etc. PPES 135 may use the event outage information to identify and/or isolate potential fault locations associated with the outages. Based on the determination that an outage event has occurred, PPES 135 may send an outage event notification to O&RS 140. The outage event notification may include outage information associated with an outage notification associated with particular power provider equipment, the outage event information, and/or information associated with fault isolation (e.g., potential fault locations, etc.).

In another example, the outage event notification may include information associated with a user interface via which a map of the geographic area may be presented for display. In some implementations, location information associated with power provider equipment, physical addresses corresponding to hash values received from OMS 130, information associated with the power grid, etc. may also be included for display via the UI.

The O&R application (resident on either NMS 130 or PPES 135) may identify an outage event that triggers an emergency management protocol and/or response when a quantity of outages is greater than an emergency threshold (e.g., an emergency threshold that is greater than the outage threshold) that may correspond to particularly wide spread outages. The O&R application may send an emergency outage event alert to O&RS 140 and/or information server 150 (e.g., associated with local, state, federal governmental authorities and/or first responders.).

The O&R application may determine that an outage event has occurred, or will occur at a future point in time, based on outage trends, such as when a quantity of outages within a period of time is increasing. The outage event may, for example, be identified when a rate of increase in the quantity of outages is greater than a threshold. In another example, an outage event may be identified when the quantity of outages is increasing in a manner that the O&R application may project that the quantity of outages may be greater than the outage threshold within a future period of time. Based on the determination that an outage event has been identified based on the outage trends, the O&R application may send an outage event notification to O&RS 140. The outage notification may include outage information associated with an outage alert associated with network terminal 120, the outage event information, location information associated with each outage, information associated with outage trends, and/or a future period of time during which the quantity of outages is projected to be greater than the outage threshold.

In yet another example, the O&R application may determine that an outage event may occur at a future point in time based on weather conditions. For example, the O&R application may communicate with information server 150 to obtain weather information, which may include weather forecasts, weather warnings, information associated with natural disasters, etc. The O&R application may use event outage information (e.g., obtained from the memory) from a prior period of time that associated with a type of weather information (e.g., a heat wave, a cold spell, storm conditions, high winds, etc.) that corresponds to the weather information obtained from information server 150. For example, the O&R application may identify that during the prior period of time, a particular quantity of outages that is greater than the outage threshold were detected. In another example, the O&R application may identify particular locations and/or portions of the power grid that may be susceptible to outages based on a quantity of outages and/or locations of the outages during the prior period of time. Based on the event outage information from a prior period of time that corresponds to the type of weather information, the O&R application may send an outage event notification that may indicate that an outage event is forecasted to occur, particular which portions of the power grid may be susceptible, projected quantities and/or locations of outages, etc.

In still another example, the O&R application may determine that an outage event may occur based on conditions on a power grid. For example, the O&R application may communicate with O&RS 140 and/or information server 150 to obtain information associated with conditions on the power grid and/or conditions that may affect the power grid. The conditions may include load imbalances within the power grid, peak periods of power consumption, brown-outs, blackouts, malfunctioning equipment, etc. The O&R application may use event outage information (e.g., obtained from the memory) from a prior period of time that is associated with a type of conditions that corresponds to the information associated with the conditions obtained from O&RS 140 and/or information server 150. For example, the O&R application may identify that during the prior period of time, a particular quantity of outages were detected that is greater than the outage threshold. In another example, the O&R application may identify that particular locations and/or portions of the power grid that are potentially susceptible to outages based on the conditions present on the power grid at the prior period of time. Based on the event outage information from a prior period of time that corresponds to the information associated with the conditions on the power grid, the O&R application may send an outage event notification which may indicate that an outage event is forecasted to occur, particular portions of the power grid that may be susceptible, projected quantities and/or locations of outages, etc.

As yet further shown in FIG. 10, if an outage event is not triggered (block 1025—NO), or after sending out the outage event notification (block 1030), and if a notification that power is restored is not received (block 1035—NO), then process 1000 may include sending a status notification (block 1040). For example, the O&R application may determine that an outage event, associated with a geographic area, is not triggered when a quantity of outages is less than the outage threshold. In another example, the O&R application may determine that an outage event is not triggered when a pattern of outages are not detected, based on a quantity of simultaneous outages (e.g., less than the simultaneous threshold) and/or co-located outages (e.g., an outage that occurs at a distance and/or area that is greater than the location threshold relative to another outage).

In another example, the O&R application may determine that an outage event is not triggered based on outage trends, such as when a quantity of outages, within a period of time, is not increasing in a manner that triggers an outage event. For example, the O&R application may not detect an outage event when a rate of increase in the quantity of outages is less than a threshold. In another example, the O&R application may not detect an outage event when the quantity of outages is not increasing in a manner that the O&R application projects that the quantity of outages are expected to be greater than the outage threshold within a future period of time.

In yet another example, the O&R application may determine that an outage event is not projected to occur at a future point in time based on weather information. For example, the O&R application may use event outage information from a prior period of time that is associated with a type of weather information obtained from information server 150. For example, the O&R application may determine that during the prior period of time, a quantity of outages were less than the outage threshold. In still another example, the O&R application may determine that an outage event is not expected to occur based on conditions present on a power grid. For example, the O&R application may identify that during the prior period of time, a quantity of outages were not greater than the outage threshold. In another example, the O&R application may identify that particular locations and/or portions of the power grid that are not susceptible to outages based on the conditions present on the power grid at the prior period of time.

Additionally, or alternatively, the O&R application may not receive a restore alert from network terminal 120/NMS 130. For example, network terminal 120 may monitor whether AC power is being received from the power grid (via an AC power outlet) and may determine that AC power has not been restored. Based on the determination that power has not been restored, network terminal 120 may send an alert that indicates that the AC power has not been restored. The alert may include information associated with network terminal 120, a time when the outage was detected, an elapsed time associated with the outage, a charge state associated with storage device 310 (FIG. 3), and/or other outage information. In another implementation, network terminal 120 may determine that AC power has not been restored and may not send an alert.

Based on the determination that the AC power has not been restored to network terminal 120, the O&R application may send a status notification, to O&RS 140, when the outage event is detected, in a manner similar to that described above (e.g., with respect to block 1025—YES), or after an outage event notification is sent to O&RS 140 in a manner similar to that described above (e.g., with respect to block 1030). The status notification may indicate that AC power has not been restored to network terminal 120. Additionally, or alternatively, the status notification may indicate an elapsed time of the outage and/or other outage information associated with network terminal 120.

As further shown in FIG. 10, if an outage event is not triggered (block 1025—NO), or after sending out the outage event indication (block 1030), and if a notification that power is restored is received (block 1035—YES), then process 1000 may include sending a notification that power is restored (block 1045). For example, the O&R application may receive a restore alert from network terminal 120/NMS 130. For example, network terminal 120 may, monitor whether AC power is being received from the power grid (e.g., via an AC power outlet) and may determine that AC power has been restored. Based on the determination that AC power has been restored, network terminal 120 may switch from receiving power from storage device 310 (FIG. 3) to the AC power source. Alternatively, or additionally, network terminal 120 may send a restore alert that indicates that the AC power has been restored. The restore alert may include information associated with network terminal 120, a charge state associated with storage device 310, a time when the AC power was restored, an elapsed time associated with the outage, and/or other outage information. In another example implementation, network terminal 120 may determine that AC power has been restored and may not send a restore alert.

Based on the determination that the AC power has been restored to network terminal 120, the O&R application may send a restore notification, to O&RS 140, when the outage event is detected, in a manner similar to that described above (e.g., with respect to block 1025—YES), or after an outage event notification is sent to O&RS 140 in a manner similar to that described above (e.g., with respect to block 1030). The restore notification may indicate that AC power has not been restored to network terminal 120. Additionally, or alternatively, the status notification may indicate an elapsed time of the outage and/or other outage information associated with network terminal 120.

As yet further shown in FIG. 10, if the outage event is not remedied (block 1050—NO), then process 1000 may include sending a status notification (block 1040). For example, the O&R application may retrieve information from an outage event data structure (e.g., from event data structure 500 of FIG. 5) from a prior period of time. Based on the quantity of outages obtained from the outage event data structure, the O&R application may determine that the quantity of outages is greater than the outages threshold and/or that quantity of outages is increasing at a rate that corresponds to an outage event. In yet another example, the O&R application may determine that weather information and/or information associated with conditions on the power grid indicate that the outage event still exists on the power grid. For example, the weather information may indicate that weather conditions have not improved (e.g., a heat wave or cold spell has not subsided, storm conditions have not dissipated, etc.), which may cause the O&R application to determine that an outage event exists. In another example, the information associated with conditions on the power grid may indicate that conditions have not improved, which may cause the O&R application to determine that an outage event is present on the power grid. Based on the determination that the outage event is present on the power grid, the O&R application may send a status notification, to O&RS 140, in a manner similar to that described above (e.g., with respect to block 1035—NO).

As still further shown in FIG. 10, if the outage event is remedied (block 1050—YES), then process 1000 may include sending a notification that the outage is remedied (block 1055). For example, the O&R application may receive the restore alert from network terminal 120/NMS 130 and/or other restore alerts associated with other network terminals 120 and may retrieve information from an outage event data structure (e.g., from event data structure 500 of FIG. 5) from a prior period of time. Based on the restore alert and/or a quantity of outages obtained from the outage event data structure, the O&R application may determine that the quantity of outages is not greater than the outages threshold. In another example, the O&R application may determine that a trend, associated with the quantity of outages, is not increasing at a rate that corresponds to an outage event. In yet another example, the O&R application may determine that, based on a decreasing quantity of outages, the outage event has been remedied and/or that the outage event may be remedied at a future point in time.

In still another example, the O&R application may determine that weather information and/or information associated with conditions on the power grid have changed, such that the outage event is no longer present. For example, the weather information may indicate that weather conditions have improved (e.g., a heat wave or cold spell has subsided, storm conditions have not materialized or have passed, etc.), which may cause the O&R application to no longer project that an outage event has occurred or is projected to occur. In another example, the information associated with conditions on the power grid have improved (e.g., a load balancing operation was performed, consumption decreased, repairs to equipment were made, etc.), which may cause the O&R application to no longer project that an outage event has occurred or is projected to occur. Based on a determination that an outage event has been remedied and/or is no longer projected to occur, the O&R application may send, to O&RS 140, a notification that the outage event has been remedied.

In this specification, various preferred embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

While series of blocks have been described, with regard to FIGS. 8-10, the order of the blocks may be modified in other implementations. Further, non-dependent blocks may be performed in parallel.

It will be apparent that systems and methods, as described above, may be implemented in many different forms of software, firmware, and hardware in the implementations illustrated in the figures. The actual software code or specialized control hardware used to implement these systems and methods is not limiting of the invention. Thus, the operation and behavior of the systems and methods were described without reference to the specific software code—it being understood that software and control hardware can be designed to implement the systems and methods based on the description herein.

Further, certain portions, described above, may be implemented as a component or logic that performs one or more functions. A component or logic, as used herein, may include hardware, such as a processor, an ASIC, or a FPGA, or a combination of hardware and software (e.g., a processor that executes software).

It should be emphasized that the terms “comprises”/“comprising,” when used in this specification, are taken to specify the presence of stated features, integers, steps or components but does not preclude the presence or addition of one or more other features, integers, steps, components or groups thereof.

No element, act, or instruction used in the present application should be construed as critical or essential to the invention unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

What is claimed is:

1. A method, comprising:
receiving, by one or more server devices and from a network terminal device installed at a subscriber premise, an alert that the network terminal device has lost primary power from a power grid;
determining, by the one or more server devices, a physical address of a location for the network terminal;
associating, by the one or more server devices, the physical address of the network terminal location with particular power grid equipment;
determining, by the one or more server devices, whether a power outage of the power grid has occurred; and
outputting, by the server device, a notification of the power outage associated with the particular power grid equipment when the power outage is determined to occur.

2. The method of claim 1, wherein associating the physical address of the network terminal location with particular power grid equipment comprises:
matching, in a subscriber data table, an identifier of the network terminal with a subscriber address; and
deriving a first hash value from the physical address using a particular hash function.

3. The method of claim 2, wherein associating the physical address of the network terminal location with particular power grid equipment further comprises:
storing an equipment table that relates multiple pieces of power grid equipment with second hash values derived from physical addresses of a power grid customer, wherein derivation of the second hash value uses the particular hash function; and
comparing the first hash value to the second hash values to identify a match.

4. The method of claim 3, wherein the notification of the power outage is not associated with a single physical address of the location for the network terminal.

5. The method of claim 3, wherein the physical address of the network terminal location from the subscriber data table and the physical addresses of the power grid customers from the equipment table are stored in the same format.

6. The method of claim 5, wherein the first hash value and the second hash values are configured to prevent reverse calculations to determine the physical address.

7. The method of claim 1, wherein the notification of the power outage includes:
an identifier for the particular power grid equipment; and
one or more of a notification code and a time.

8. The method of claim 1, wherein outputting a notification of the power outage includes notifying a power provider that is responsible for managing or operating the power grid.

9. The method of claim 1, wherein the notification of the power outage does not include the physical address of the network terminal location.

10. The method of claim 1, further comprising:
receiving, from the network terminal device, another alert that the network terminal device is receiving power from the power grid;
determining whether the power outage of the power grid has been remedied; and
outputting another notification that the power outage has been remedied when the power outage is determined to have been remedied, wherein the other notification includes an indication of the particular power grid equipment.

11. The method of claim 1, wherein determining whether a power outage of the power grid has occurred includes:
analyzing a plurality of other alerts received from a plurality of respective network terminal devices.

12. A system comprising:
a first server device including:
a first memory to store:
a plurality of instructions, and
a subscriber data structure associating multiple network terminal devices with addresses of corresponding subscriber premises that receive power from a power grid; and
a first processor configured to:
receive, from a network terminal device installed at a subscriber premise, an alert that the network terminal device has lost primary power from the power grid,
determine, based on the subscriber data structure, a physical address of a location for the network terminal,
generate a first hash value based on the physical address of the network terminal location,
determine whether a power outage within the power grid has occurred, and
output an indication of the power outage that includes the first hash value when the power outage is determined to have occurred.

13. The system of claim 12, further comprising:
a second server device including:
a second memory to store:
a plurality of instructions, and
an equipment data structure that relates multiple pieces of power grid equipment with second hash values derived from physical addresses of power grid customers; and
a second processor configured to:
receive, from the first server device, the indication of the power outage,
compare the first hash value to the second hash values to identify a match, and
output a notification of the power outage that includes particular power grid equipment related to the matching one of the second hash values.

14. The system of claim 13, wherein the first hash value and the second hash value are derived using the same hash function.

15. The system of claim 13, wherein the physical address of the network terminal location and the physical addresses of the power grid customers are stored in the same format.

16. The system of claim 13, wherein, when outputting the notification of the power outage, the second processor is further configured to:
notify a power provider that is responsible for managing or operating the power grid.

17. The system of claim 12, wherein the notification of the power outage includes:
an identifier for the particular power grid equipment; and
one or more of a notification code and a time.

18. A method, comprising:
generating, by a server device, a reference database of network terminal identifiers for network terminals associated with a service provider and power equipment identifiers for power equipment associated with a power provider;
receiving, by the server device and from a network terminal device installed at a subscriber premise, an outage alert that the network terminal device has lost primary power from a power grid, wherein the outage alert includes a network terminal identifier for the network terminal device;
matching, by the server device and based on the reference database, the network terminal identifier in the outage alert to a corresponding power equipment identifier; and
sending, by the server device and to a device associated with the power provider, an outage notification that includes information from the outage alert and the power equipment identifier.

19. The method of claim 18, wherein generating the reference database includes:
receiving, from a device associated with the service provider, a first database excerpt including network terminal identifiers and first hash values of corresponding subscriber addresses;
receiving, from the device associated with the power provider, a second database excerpt including power equipment identifiers and second hash values of corresponding addresses for power equipment; and
matching the first hash values to the second hash values to create the reference database.

20. The method of claim 19, wherein each of the power equipment identifiers is associated with more than one of the second hash values of corresponding addresses such that matching the network terminal identifier in the outage alert to the corresponding power equipment identifier precludes identification of a particular one of the subscriber addresses.

21. The method of claim 19, wherein the server device is managed by a third party that is different than the service provider and the power provider.

22. The method of claim 19, wherein the subscriber addresses and the address for power equipment include physical addresses in a standard format.

23. A non-transitory computer-readable medium comprising one or more instructions to:
generate a reference database of network terminal identifiers for network terminals associated with a service provider and power equipment identifiers for power equipment associated with a power provider;
receive an outage alert originating from a network terminal device installed at a subscriber premise, the outage alert indicating that the network terminal device has lost primary power from a power grid, wherein the outage alert includes a network terminal identifier for the network terminal device;
match, based on the reference database, the network terminal identifier in the outage alert to a corresponding power equipment identifier; and
send, to a device associated with the power provider, an outage notification that includes information from the outage alert and the power equipment identifier.

24. The non-transitory computer-readable medium of claim 23, further comprising instructions to:
receive, from a device associated with the service provider, a first database excerpt including network terminal identifiers and first hash values of corresponding subscriber addresses; and
receive, from the device associated with the power provider, a second database excerpt including power equipment identifiers and second hash values of corresponding addresses for power equipment, wherein each of the power equipment identifiers is associated with more than one of the second hash values.
